(19) United States
(12) Patent Application Publication
(10) Pub. No.: US 2026/0088821 A1
(43) Pub. Date: Mar. 26, 2026

(54) CLOCK COMPENSATION ACROSS DEVICES

(71) Applicant: APPLE INC., CUPERTINO, CA (US)

(72) Inventors: YAIR TALKER, SARATOGA, CA (US); RIKI HASSON, CALGARY (CA); MOHAMED H. ABU-RAHMA, MOUNTAIN VIEW, CA (US); MAYUR V. JOSHI, SAN CARLOS, CA (US); BO ZHAO, LOS ALTOS, CA (US); JINGCHENG WANG, SANTA CLARA, CA (US)

(21) Appl. No.: 19/015,144

(22) Filed: Jan. 9, 2025

Related U.S. Application Data
(60) Provisional application No. 63/699,560, filed on Sep. 26, 2024.

(51) Int. Cl. H03L 7/081; H03L 7/085

(52) U.S. Cl. CPC H03L 7/0812; H03L 7/085

(57) ABSTRACT

A clock compensation circuit of a first integrated circuit includes a phase detector circuit. The phase detector circuit includes a first input operative to receive a first clock signal from a second integrated circuit and a second input operative to receive a second clock signal for a circuit of the first integrated circuit. The phase detector circuit is configured to output a first control signal indicating whether the first and second clock signals are synchronized, and a second control signal indicating whether a phase of clock signals is different. The clock compensation circuit also includes a control circuit, responsive to one or more of the first and second control signals, and configured to generate one or more delay control signals. The clock compensation circuit also includes a delay circuit configured to apply a delay to the second clock signal based on the one or more delay control signals.

### CROSS-REFERENCE TO RELATED APPLICATION

This application is a non-provisional utility application for patent entitled to a filing date and claiming the benefit of earlier-filed U.S. Provisional Patent Application No. 63/699,560, filed Sep. 26, 2024, herein incorporated by reference in its entirety.

### BACKGROUND

### Technical Field

Embodiments described herein relate to integrated circuits, and more particularly, to clock compensation.

### Description of the Related Art

Modern computer systems may include multiple circuits blocks (e.g., integrated circuits) designed to perform various functions. For example, such circuit blocks may include processors and/or processor cores configured to execute software or program instructions. Additionally, the circuit blocks may include memory circuits, mixed-signal or analog circuits, and the like. The integrated circuits and/or portions of the integrated circuits often use clocks and/or clock signals to operate. For example, a clock circuit (e.g., a phase-locked loop circuit, an oscillator circuit, etc.) may generate a clock signal and the clock signal may be used by an integrated circuit (or a subcircuit/portion of the integrated circuit) to control timing of operations, to drive operations/actions, etc.

Although integrated circuits may use clock circuits and/or clock signals to operate, not all integrated circuits include a clock circuit. When an integrated circuit does not include a clock circuit (or some other appropriate circuit/component for generating a clock signal), the integrated circuit may use the clock signal received from another integrated circuit (e.g., a clock source, a master clock/circuit, a primary clock/circuit, etc.). In addition, the two integrated circuits (e.g., the first integrated circuit that includes a clock circuit and the second integrated circuit that does not include a clock circuit) may be located on different dies (e.g., on different silicon dies, different silicon chips, different voltages, different temperatures, etc.). This may cause the timing of the clock signal generated by the first integrated circuit to differ from the timing of the clock signal received by the second integrated circuit. For example, after an initial boot or startup, when the power received from the power supply may be dynamically increased/lowered based on demand, the timing of the clock signal generated by the first integrated circuit may be offset or skewed from the timing of the clock signal received by the second integrated circuit.

### SUMMARY OF VARIOUS EMBODIMENTS

Various embodiments of a system are disclosed. The system includes a first integrated circuit. The first integrated circuit includes a clock generator circuit configured to generate a first clock signal, and a first circuit configured to receive the first clock signal. The apparatus also includes a second integrated circuit configured to provide a second clock signal to a second circuit based on the first clock signal. The second integrated circuit includes a phase detector circuit configured to compare the first clock signal and the second clock signal. The second integrated circuit further includes a control circuit configured to cause a delay to be applied to the second clock signal based on the comparison.

### BRIEF DESCRIPTION OF THE DRAWINGS

The following detailed description makes reference to the accompanying drawings, which are now briefly described.

FIG. 1 illustrates diagram of an example system, in accordance with one or more embodiments of the present disclosure.

FIG. 2 illustrates a diagram of a phase detector circuit, in accordance with one or more embodiments of the present disclosure.

FIG. 3 illustrates an example timing diagram, in accordance with one or more embodiments of the present disclosure.

FIG. 4 illustrates a flow diagram depicting an embodiment of a method for synchronizing clock signals, in accordance with one or more embodiments of the present disclosure.

FIG. 5 illustrates a block diagram of an example system, in accordance with one or more embodiments of the present disclosure.

While the disclosure is susceptible to various modifications and alternative forms, specific embodiments thereof are shown by way of example in the drawings and will herein be described in detail. It should be understood, however, that the drawings and detailed description thereto are not intended to limit the disclosure to the particular form illustrated, but on the contrary, the intention is to cover all modifications, equivalents and alternatives falling within the spirit and scope of the present disclosure as defined by the appended claims. The headings used herein are for organizational purposes only and are not meant to be used to limit the scope of the description. As used throughout this application, the word “may” is used in a permissive sense (i.e., meaning having the potential to), rather than the mandatory sense (i.e., meaning must). Similarly, the words “include,” “including,” and “includes” mean including, but not limited to.

### DETAILED DESCRIPTION OF EMBODIMENTS

As discussed above, devices, integrated circuits and/or portions of the integrated circuits often use clocks and/or clock signals to operate. Although integrated circuits may use clock signals to operate, not all integrated circuits include a clock circuit. When an integrated circuit does not include a clock circuit (or some other appropriate circuit/component for generating a clock signal), the integrated circuit may use the clock signal received from another integrated circuit (e.g., a clock source, a master clock/circuit, a primary clock/circuit, etc.). In addition, the two integrated circuits (e.g., the first integrated circuit that includes a clock circuit and the second integrated circuit that does not include a clock circuit) may be located on different dies (e.g., on different silicon dies, different silicon chips, etc.). This may cause the timing of the clock signal generated by the first integrated circuit to differ from the timing of the clock signal received by the second integrated circuit.

In one embodiment, it may be useful to synchronize the clock signal received by the second integrated circuit with the clock signal generated by the first integrated circuit. This may allow the devices/circuits of the two integrated circuits to operate more quickly, efficiently, and/or with lower latency. The embodiments, implementations, examples, etc., described herein may allow two devices to synchronize clock signals without more complex/expensive hardware such as asynchronous first-in-first-out (FIFO) circuits, which may also improve the performance/speed of the devices/circuits.

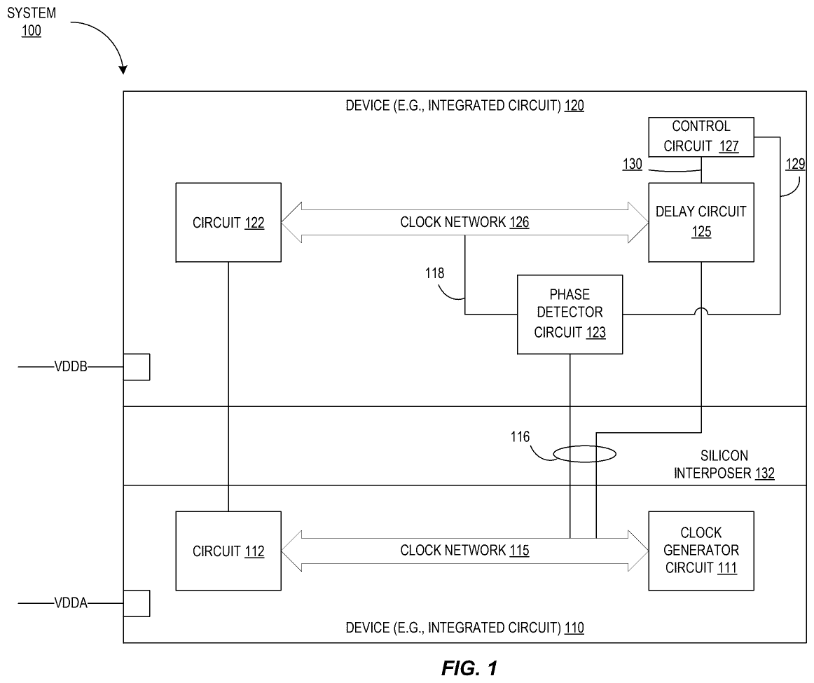

FIG. 1 illustrates diagram of an example system 100, in accordance with one or more embodiments of the present disclosure. The system includes devices 110 and 120. The devices 110 and 120 may each be one or more of circuits (e.g., integrated circuits, circuit blocks), logic, processing devices, and/or other components that may be included in various computing/electronic devices. In one embodiment, devices 110 and 120 may be in separate dies, such as separate system on chips (SOCs). For example, device 110 may be part of a first die (e.g., a first silicon die) and device 120 may be part of a second die (e.g., a second, separate silicon die). In addition, device 110 may receive power signal VDDA from a first voltage domain (e.g., a first power domain) and device 120 may receive power signal VDDB from a second voltage domain (e.g., a second power domain, a different voltage domain that uses different voltage levels, etc.).

Device 110 includes a clock generator circuit 111. The clock generator circuit 111 may be any circuit, device, component, module, etc., that may generate a clock signal. For example, the clock generator circuit 111 may include a phase-locked loop (PLL) circuit, an oscillator, and/or another appropriate device, circuit, component, etc., for generating the clock signal. In one example, the same PLL is shared between the different dies so that one die need not have a PLL circuit. In this example, a same PLL provides a clock signal for both the circuit 112 and the circuit 122 that perform operations with each other.

Device 110 also includes a circuit 112. Circuit 112 may be a combination of circuits, devices, and/or components that may be used to perform various tasks, functions, operations, etc., in the device 110. Circuit 112 may be coupled to clock generator circuit 111 via clock network 115. Clock network 115 may be one or more circuits, devices, components, etc., that may provide the clock signal 116 generated by the clock generator circuit 111 to circuit 112 (and other circuits within device 110). Clock network 115 may also be referred to as a spine, a clock spine, etc. Circuit 112 may receive the clock signal via clock network 115 and may use the clock signal to control timing of operations, to drive operations/actions, etc.

Device 120 includes circuit 122 and active clock compensation circuitry that compensates a clock signal across different integrated circuits during normal operation, that in this example includes a phase detector circuit 123, delay circuit 125, and control circuit 127. Circuit 122 may be a combination of circuits, devices, and/or components that may be used to perform various tasks, functions, operations, etc., in the device 110. Phase detector circuit 123, delay circuit 125, and control circuit 127 are discussed in more detail below.

As illustrated in FIG. 1, device 120 does not include a clock generator circuit. However, circuit 122 may use a clock signal 118 to operate properly. The clock network 115 may also be coupled circuits in the device 120 via various traces, connections, wires, lines, etc. For example, the clock network 115 is coupled to delay circuit 125 and phase detector circuit 123. The clock network 115 may provide the clock signal 118 to the phase detector circuit 123 and the delay circuit 125. The clock signal 118 may then be provided to the circuit 122 via the clock network 126.

Also as illustrated in FIG. 1, the circuit 122 may be coupled to the circuit 112 via one or more traces, lines, connections, wires, etc. The circuit 122 and the circuit 112 may communicate with each other and may synchronize/coordinate the performance of operations, tasks, functions, etc. For example, circuit 122 may perform a first operation and may coordinate the first operation with a second operation performed by circuit 112. Because circuits 122 and 112 may synchronize/coordinate operations, functions, tasks, etc., it may be useful to have the timing of the clock signal used by circuit 122 be synchronized with the timing of the clock signal used by circuit 112. However, because the clock signal 116 is shared by both devices 110 and 120 and transmitted from one device/die to another device/die, so that the clock signal is crossing dies, such as through silicon interposer 132 or other sources of delay, the timing of the clock signal 118 received by circuit 122 may be skewed from the timing of the clock signal used by circuit 112. In this example the devices 110 and 120 are shown to be dies or chips in a 3-D stacked relation, however a side-by-side configuration may be employed or any suitable interconnect configuration may be employed.

The embodiments, implementations, and/or examples described herein provide a phase detector circuit 123, a control circuit 127, and a delay circuit 125 to compensate for the difference (e.g., the skew or offset) in the clock signal 116 received by circuit 112 and the clock signal 118 received by circuit 122. For example, phase detector circuit 123, control circuit 127, and delay circuit 125 may be used to actively compensate for the difference in timing in the clock signals received by circuit 112 and 122. A delay may be added to the clock signal received by the device 120 to allow the clock signal received by the device 120 to synchronize with the clock signal generated by the clock generator circuit 111. For example, the compensation between the clock signal received by the circuit 112 and the clock signal received by the circuit 122 may be performed periodically and/or continuously, as the devices 110 and 120 operate during normal operation, beyond an initial boot up period.

In one embodiment, the phase detector circuit 123 may receive a first clock signal 116 provided to circuit 112 and a second clock signal 118 provided to circuit 122. The second clock signal may be based on the first clock signal (that was generated by the clock generator circuit 111), as discussed above. The phase detector circuit 123 may compare first clock signal with the second clock signal to determine an amount of skew, offset, etc., between the first clock signal and the second clock signal. The phase detector circuit 123 may provide one or more control signals 129 to the control circuit 127 indicating the amount of skew/offset/phase difference between the first clock signal and the second clock signal. The control circuit 127 may send one or more delay control signals 130 to the delay circuit 125. In an implementation, the control circuit includes a finite state machine configured to carry out the operations described herein, however any suitable circuit may be employed.

In one embodiment, the delay circuit 125 may increase and/or decrease an amount of delay applied to the second clock signal 118 to synchronize the timing of the first clock 116 signal, and the second clock signal 118. The delay circuit 125 may include an appropriate combination of circuits, devices, components, etc., for applying a delay to an input signal to generate a delayed output signal. For example, the delay circuit 125 may include a plurality of gated capacitors. In another example, the delay circuit 125 may further include a series/chain of inverters.

In one embodiment, phase detector circuit 123, control circuit 127, and delay circuit 125 may allow for more efficient operation of the device 110 and 120 (e.g., of circuits 112 and 122). For example, synchronizing the timing of the clock signals used by circuits 112 and 122 may allow the circuits 112 and 122 to perform operations more quickly and/or efficiently, such as providing high speed synchronous data communication between chips. In addition, using phase detector circuit 123, control circuit 127, and delay circuit 125 may allow the devices 110 and 120 to synchronize clock signals without using more expensive or complicated hardware/circuits (e.g., asynchronous first-in-first-out (FIFO) circuits) for synchronizing clock signals. Although only one clock spine is shown on device 120 for simplicity, the phase detector circuit 123, control circuit 127 and delay circuit 125 can be replicated, if desired, for other clock spines on the device 120 and the other clock spines may use a prior compensated clock signal from another spice as a respective reference clock signal. However, any suitable configuration may be employed including sharing compensation control circuitry or other circuitry among splines as desired.

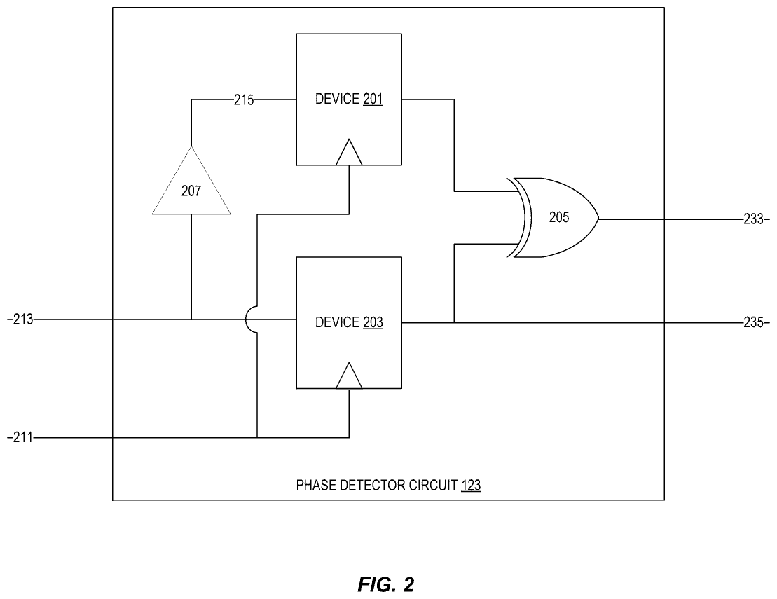

FIG. 2 illustrates a diagram of an example phase detector circuit 123, in accordance with one or more embodiments of the present disclosure. As illustrated in FIG. 2, the phase detector circuit 123 includes a device 201, device 203, XOR circuit 205, and buffer 207.

As illustrated in FIG. 2, the phase detector circuit 123 may receive a first clock signal 211 and a second clock signal 213. The first clock signal 211 may be a reference clock signal. For example, the first clock signal 211 may be the clock signal that is generated by clock generator circuit 111. The second clock signal 213 may be the clock signal that is received from clock network 126, as illustrated in FIG. 1 and in some implementations is a feedback clock signal that has been previously skew compensated by the delay circuit 125 to align with the first clock signal provided by the clock generator circuit 111 on the device 110. In this example, the second clock signal 213 is also passed through buffer 207. In one embodiment, the buffer 207 may adjust the timing of the second clock signal 213 to generate an adjusted clock signal 215. The adjusted clock signal 215 may represent a threshold skew/offset that may be allowed between the first clock signal 211 and the second clock signal 213.

The first clock signal 211 is provided to devices 201 and 203, such as suitable latches. The second clock signal 213 is provided to device 203 and the adjusted clock signal 215 is provided to the device 201. In one embodiment, device 203 may compare the first clock signal 211 (e.g., the reference clock signal) with second clock signal 213 (the feedback clock signal). The device 203 may output a high or a low (e.g., a logical 0 or a logical 1) based on whether the timing of first clock signal 211 is different than, such as ahead or behind, the timing of second clock signal 213. For example, if the timing of second clock signal 213 is behind the timing of first clock signal 211, the device 203 may output a 0. In another example, if the timing of second clock signal 213 is ahead of the timing of first clock signal 211, the device 203 may output a 1.

In one embodiment, device 201 may compare the first clock signal 211 (e.g., the reference clock signal) with adjusted clock signal 215. The device 201 may output a high or a low (e.g., a logical 0 or a logical 1) based on whether the timing of first clock signal 211 is ahead or behind the timing of adjusted clock signal 215. For example, if the timing of adjusted clock signal 215 is behind the timing of first clock signal 211, the device 201 may output a 0. In another example, if the timing of adjusted clock signal 215 is ahead of the timing of first clock signal 211, the device 201 may output a 1.

The output of device 201 and the output of device 203 are provided to XOR circuit 205. The XOR circuit 205 may compare the output of device 201 and the output of device 203 to determine whether the second clock signal 213 is synchronized, locked, etc., with the first clock signal 211. The XOR circuit 205 may determine that the second clock signal 213 is synchronized with the first clock signal 211 if the timing of the first clock signal is between the timing of the second clock signal 213 and the adjusted clock signal 215 (e.g., if device 203 outputs a 0 and device 201 outputs a 1). The XOR circuit 205 may determine that the second clock signal 213 is not synchronized with the first clock signal 211 if the timing of the first clock signal is ahead of the timing of the adjusted clock signal 215 (e.g., both device 201 and 203 output a 0). The XOR circuit 205 may also determine that the second clock signal 213 is not synchronized with the first clock signal 211 if the timing of the first clock signal is behind of the timing of the adjusted clock signal 215 (e.g., both device 201 and 203 output a 1).

In one embodiment, the phase detector circuit 123 (e.g., XOR circuit 205) may output signal 233. If signal 233 is high (e.g., a logical 1), this may indicate that the first clock signal 211 and the second clock signal 213 are synchronized, locked, etc. If signal 233 is low (e.g., a logical 0), this may indicate that the first clock signal 211 and the second clock signal 213 are not synchronized, are not locked, etc. The phase detector circuit 123 may also output signal 235. If the first clock signal 211 and the second clock signal 213 are not synchronized, signal 235 may indicate whether a phase between the clock signals is different, such as that the timing of the second clock signal 213 is ahead of or behind the timing of the first clock signal 211. For example, if the signal 235 is low, this may indicate that the timing of the second clock signal 213 is behind the timing of the first clock signal 211. In another example, if the signal 235 is high, this may indicate that the timing of the second clock signal 213 is ahead of the timing of the first clock signal 211. Thus, when the signal 233 is high this may indicate that the first clock signal 211 and the second clock signal 213 are delayed from each other, but at a known delay (e.g., the delay introduced by buffer 207 may be known). The control circuit 127, in one example, uses the signals 233 and 235 to index a stored look up table that contains data representing corresponding delay values that are used to program a programmable delay line to add or remove delay for the second clock signal to align the second clock signal with the first clock signal from the device 110. In one implementation, the delay-line includes a chain of selectable inverters for coarse correction and a series of switchable parallel coupled gate capacitors for fine tuning. The delay-line receives the first clock signal as input and under control of the control circuit, outputs the second clock signal by applying a suitable amount of delay if needed when the clock signal are not synchronized. However, any suitable delay line configuration may be employed. If desired, the depth of the delay-line can be based upon time domain simulations of the clock distribution covering a wide range of operating points and silicon materials to ensure it can compensate for a large variation in possible skew between chips. In some implementations, the delay-line can reside on a quiet voltage rail to ensure minimum self-induced jitter.

As discussed above, the phase detector circuit 123 may compare first clock signal 211 with the second clock signal 213 to determine an amount of skew, offset, etc., between the first clock signal 211 and the second clock signal 213. The phase detector circuit 123 may output the signals 233 and 235 to the control circuit 127 (illustrated in FIG. 1). The signal 233 (e.g., a control signal) indicates whether the clocks are in sync and if not in sync, signal 235 indicates whether the first clock signal 211 is behind or ahead of the second clock signal 213 so that the control circuit 127 may control the amount of delay generated by the delay circuit 125 and control the direction to shift the delay.

In one embodiment, the phase detector circuit 123 may periodically and/or continuously determine an amount of skew, offset, etc., between the first clock signal 211 and the second clock signal 213. For example, as the devices 110 and 120 continue to operate during normal operation, various operational or electrical parameters associated with the devices 110 and 120 may change. For example, the temperature of the devices 110 and/or 120 may change (e.g., may increase or may get hotter). In another example, voltage levels of the devices 110 and/or 120 may change (e.g., may increase or decrease). These operational or electrical parameters may affect the amount of skew, offset, etc., between the first clock signal and the second clock signal. Periodically and/or continuously determining the amount of skew, offset, etc., between the first clock signal and the second clock signal may allow the device 120 to keep second clock signal 213 in sync with the first clock signal 211. As shown, the second clock signal is fed back into the phase detector circuit so that a prior compensated signal can get iteratively re-adjusted (e.g., compensated) until the phases of the clock signal are locked. In some implementations, the phase detector circuit, control circuit and delay circuit provide a closed loop, active compensation control mechanism during normal operation to the clock signal provided to the device 120 from device 110 and dynamically maintains low clock skew between different chips that share a source clock and that may be manufactured from the same or different fabrication material and that are tied to the same or different voltage rails. The clock compensation circuitry performs the comparing of the first clock signal and the second clock signal and adjusting of the delay of the second clock signal during normal operation of the first integrated circuit and the second integrated circuit. This is done iteratively as needed, after a delay has previously been applied, by sending updated delay control signals after a previous delay has been applied. When needed, the clock compensation circuitry re-adjusts the delay applied to the second clock signal until the second clock signal is synchronized with the first clock signal.

In one embodiment, the amount of time for the phase detector circuit 123 to detect offset/skewed clock signals and for the control circuit 127 to adjust the clock signals, may be smaller than the amount of time for other dynamic phenomena/conditions in the device (e.g., supply ramp and temperature gradients) to affect the offset of the clock signals. This may allow the phase detector circuit 123 and/or the control circuit 127 to compensate for the effects the phenomena/conditions may have on the first clock signal 211 and/or second clock signal 213. In some implementations, a programmable delay-circuit, such as a configurable delay line, compensates for skew during an initial boot sequence and then tracks any additional skew imposed by changes of voltage/temperature drifts during normal operation using a closed loop phase-detection sensor and enforcing fine tune adjustment in the delay-line. This can result in a fast response time that can track and correct skew due to changes happening in the system while providing a type of synchronous data communication crossing between the chips based on compensating a clock provided from one chip to the other chip.

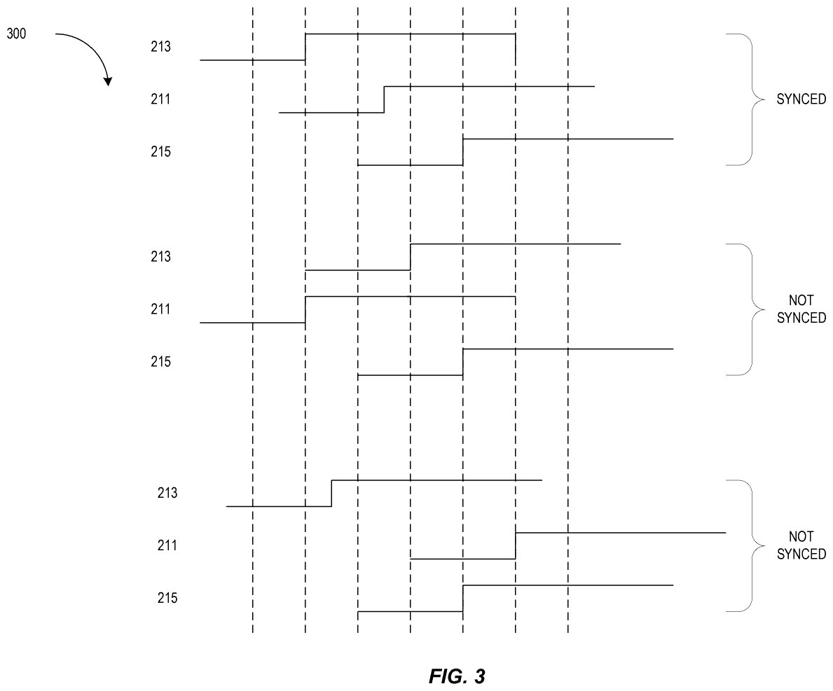

FIG. 3 illustrates an example timing diagram 300, in accordance with one or more embodiments of the present disclosure. The timing diagram 300 illustrates the values of various clock signals used by the phase detector circuit 123 (illustrated in FIG. 2) at various points in time. For example, the timing diagram 300 includes first clock signal 211 (e.g., a reference clock signal), second clock signal 213, and adjusted clock signal 215. The timing diagram 300 illustrates changes in the various signals (e.g., increase/decrease in the values/voltages of the signals) over time (e.g., time increase going from left to right).

As illustrated by the top three clock signals, the second clock signal 213 may be in sync with the first clock signal 211 because the timing of the first clock signal 211 is between the timings of second clock signal 213 and adjusted clock signal 215.

As illustrated by the middle three clock signals, the second clock signal 213 may not be in sync with the first clock signal 211 because the timing of the first clock signal 211 is behind the timings of second clock signal 213 and adjusted clock signal 215.

As illustrated by the bottom three clock signals, the second clock signal 213 may not be in sync with the first clock signal 211 because the timing of the first clock signal 211 is ahead of the timings of second clock signal 213 and adjusted clock signal 215.

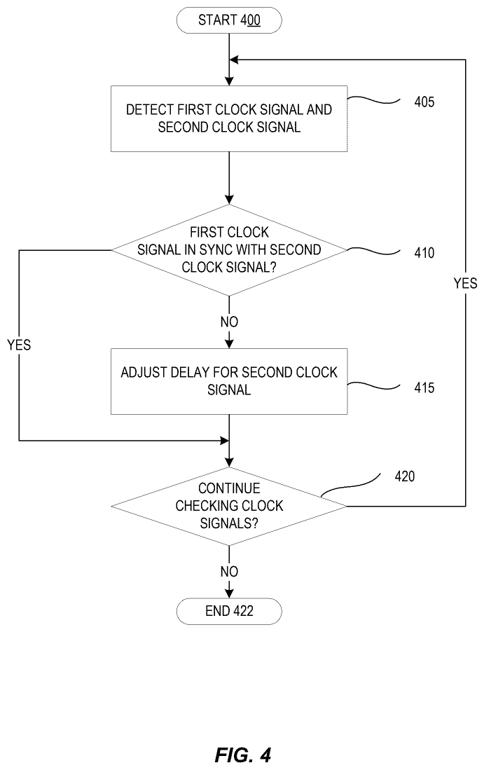

FIG. 4 illustrates a flow diagram depicting an embodiment of a method for synchronizing clock signals, in accordance with one or more embodiments of the present disclosure. The method, which may be applied to one or more of device 110, device 120, phase detector circuit 123, delay circuit 125, and/or control circuit 127, as illustrated in FIGS. 1 to 2, starts at the block 400.

The method includes detecting and/or measuring a first clock signal (e.g., a reference clock signal) and a second clock signal (e.g., a clock signal provided to one device by another device) at block 405. At block 410, the method includes determining whether the first clock signal is synchronized with the second clock signal. For example, an adjusted clock signal may be generated based on the second clock signal and the first clock signal may be compared with the second clock signal and the adjusted clock signal, as discussed above.

If the first clock signal is not in sync with the second clock signal, the timing for the second clock signal is adjusted at block 415. For example, additional delay may be applied to the second clock signal. If the first clock signal is in sync with the second clock signal, the method includes determining whether to continue checking clock signals at block 420. For example, if the devices 110 and 120 should continue operating, the method may continue checking clock signals. If the method should not continue checking clock signals, the method ends as shown in block 422. If the method should continue checking clock signals, the method proceeds to block 405.

Stated another way, in one example, during boot of the two chips, the control circuit 127 checks whether the phase detector circuit is “locked”. If it is not, it will shift a coarse/fine adjustment of the delay-line in the direction indicated by the phase-detector, a lead indication will result in increasing delay and a lag indication will result in decreasing delay for the second clock signal to compensate for the difference between the first clock signal (off-chip source clock) and the second clock signal. This takes place iteratively until the phase-detector circuit indicates “locked”. Any skew between the two clock distributions of the two chips that was induced by the usage of two different materials will be compensated at this boot stage. From this point on the chip functional traffic is launched during normal operation. Any change in voltage or temperature is regarded to be slow enough so that the control circuit 127 will actively identify the loss of “locked” indication and trigger a further decrease/increase in the delay-line during normal operation of the chips.

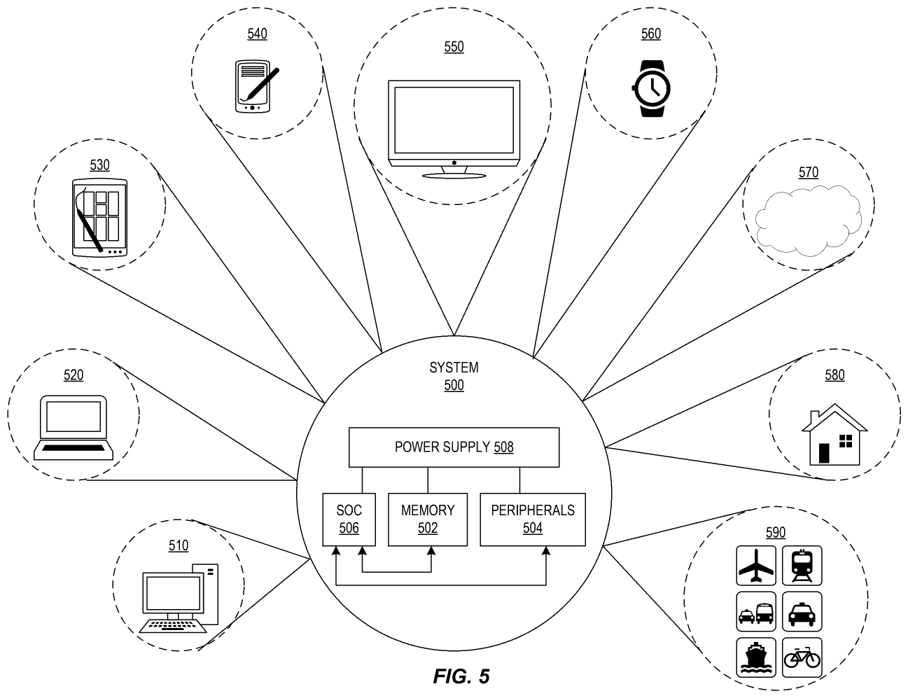

FIG. 5 illustrates a block diagram of an example system 500, in accordance with one or more embodiments of the present disclosure. The system 500 may incorporate and/or otherwise utilize the circuits, devices, components, methods, functions, and/or mechanisms described herein. In the illustrated embodiment, the system 500 includes at least one instance of a system on chip (SoC) 506 which may include multiple types of processing units, such as a central processing unit (CPU), a graphics processing unit (GPU), or otherwise, a communication fabric, and interfaces to memories and input/output devices. In some embodiments, one or more processors in SoC 506 includes multiple execution lanes and an instruction issue queue. In various embodiments, SoC 506 is coupled to external memory 502, peripherals 504, and power supply 508. The system 500 may use plates (with regions and/or vias) that are coupled to various components (e.g., coupled to SoC 506).

A power supply 508 is also provided which supplies the supply voltages to SoC 506 as well as one or more supply voltages to the memory 502 and/or the peripherals 504. In various embodiments, power supply 508 represents a battery (e.g., a rechargeable battery in a smart phone, laptop or tablet computer, or other device). In some embodiments, more than one instance of SoC 506 is included (and more than one external memory 502 is included as well).

The memory 502 is any type of memory, such as dynamic random access memory (DRAM), synchronous DRAM (SDRAM), double data rate (DDR, DDR2, DDR3, etc.) SDRAM (including mobile versions of the SDRAMs such as mDDR3, etc., and/or low power versions of the SDRAMs such as LPDDR2, etc.), RAMBUS DRAM (RDRAM), static RAM (SRAM), etc. One or more memory devices are coupled onto a circuit board to form memory modules such as single inline memory modules (SIMMs), dual inline memory modules (DIMMs), etc. Alternatively, the devices are mounted with a SoC or an integrated circuit in a chip-on-chip configuration, a package-on-package configuration, or a multi-chip module configuration.

The peripherals 504 include any desired circuitry, depending on the type of system 500. For example, in one embodiment, peripherals 504 includes devices for various types of wireless communication, such as Wi-Fi, Bluetooth, cellular, global positioning system, etc. In some embodiments, the peripherals 504 also include additional storage, including RAM storage, solid state storage, or disk storage. The peripherals 504 include user interface devices such as a display screen, including touch display screens or multitouch display screens, keyboard or other input devices, microphones, speakers, etc.

As illustrated, system 500 is shown to have application in a wide range of areas. For example, system 500 may be utilized as part of the chips, circuitry, components, etc., of a desktop computer 510, laptop computer 520, tablet computer 530, cellular or mobile phone 540, or television 550 (or set-top box coupled to a television). Also illustrated is a smartwatch and health monitoring device 560. In some embodiments, smartwatch may include a variety of general-purpose computing related functions. For example, smartwatch may provide access to email, cellphone service, a user calendar, and so on. In various embodiments, a health monitoring device may be a dedicated medical device or otherwise include dedicated health related functionality. For example, a health monitoring device may monitor a user's vital signs, track proximity of a user to other users for the purpose of epidemiological social distancing, contact tracing, provide communication to an emergency service in the event of a health crisis, and so on. In various embodiments, the above-mentioned smartwatch may or may not include some or any health monitoring related functions. Other wearable devices are contemplated as well, such as devices worn around the neck, devices that are implantable in the human body, glasses designed to provide an augmented and/or virtual reality experience, and so on.

System 500 may further be used as part of a cloud-based service(s) 570. For example, the previously mentioned devices, and/or other devices, may access computing resources in the cloud (i.e., remotely located hardware and/or software resources). Still further, system 500 may be utilized in one or more devices of a home other than those previously mentioned. For example, appliances within the home 580 may monitor and detect conditions that warrant attention. For example, various devices within the home (e.g., a refrigerator, a cooling system, etc.) may monitor the status of the device and provide an alert to the homeowner (or, for example, a repair facility) should a particular event be detected. Alternatively, a thermostat may monitor the temperature in the home and may automate adjustments to a heating/cooling system based on a history of responses to various conditions by the homeowner. Also illustrated in FIG. 5 is the application of system 500 to various modes of transportation 590. For example, system 500 may be used in the control and/or entertainment systems of aircraft, trains, buses, cars for hire, private automobiles, waterborne vessels from private boats to cruise liners, scooters (for rent or owned), and so on. In various cases, system 500 may be used to provide automated guidance (e.g., self-driving vehicles), general systems control, and otherwise. These any many other embodiments are possible and are contemplated. It is noted that the devices and applications illustrated in FIG. 5 are illustrative only and are not intended to be limiting. Other devices are possible and are contemplated.

The present disclosure includes references to “an “embodiment” or groups of “embodiments” (e.g., “some embodiments” or “various embodiments”). Embodiments are different implementations or instances of the disclosed concepts. References to “an embodiment,” “one embodiment,” “a particular embodiment,” and the like do not necessarily refer to the same embodiment. A large number of possible embodiments are contemplated, including those specifically disclosed, as well as modifications or alternatives that fall within the spirit or scope of the disclosure.

This disclosure may discuss potential advantages that may arise from the disclosed embodiments. Not all implementations of these embodiments will necessarily manifest any or all of the potential advantages. Whether an advantage is realized for a particular implementation depends on many factors, some of which are outside the scope of this disclosure. In fact, there are a number of reasons why an implementation that falls within the scope of the claims might not exhibit some or all of any disclosed advantages. For example, a particular implementation might include other circuitry outside the scope of the disclosure that, in conjunction with one of the disclosed embodiments, negates or diminishes one or more the disclosed advantages. Furthermore, suboptimal design execution of a particular implementation (e.g., implementation techniques or tools) could also negate or diminish disclosed advantages. Even assuming a skilled implementation, realization of advantages may still depend upon other factors such as the environmental circumstances in which the implementation is deployed. For example, inputs supplied to a particular implementation may prevent one or more problems addressed in this disclosure from arising on a particular occasion, with the result that the benefit of its solution may not be realized. Given the existence of possible factors external to this disclosure, it is expressly intended that any potential advantages described herein are not to be construed as claim limitations that must be met to demonstrate infringement. Rather, identification of such potential advantages is intended to illustrate the type(s) of improvement available to designers having the benefit of this disclosure. That such advantages are described permissively (e.g., stating that a particular advantage “may arise”) is not intended to convey doubt about whether such advantages can in fact be realized, but rather to recognize the technical reality that realization of such advantages often depends on additional factors.

Unless stated otherwise, embodiments are non-limiting. That is, the disclosed embodiments are not intended to limit the scope of claims that are drafted based on this disclosure, even where only a single example is described with respect to a particular feature. The disclosed embodiments are intended to be illustrative rather than restrictive, absent any statements in the disclosure to the contrary. The application is thus intended to permit claims covering disclosed embodiments, as well as such alternatives, modifications, and equivalents that would be apparent to a person skilled in the art having the benefit of this disclosure.

For example, features in this application may be combined in any suitable manner. Accordingly, new claims may be formulated during prosecution of this application (or an application claiming priority thereto) to any such combination of features. In particular, with reference to the appended claims, features from dependent claims may be combined with those of other dependent claims where appropriate, including claims that depend from other independent claims. Similarly, features from respective independent claims may be combined where appropriate.

Accordingly, while the appended dependent claims may be drafted such that each depends on a single other claim, additional dependencies are also contemplated. Any combinations of features in the dependent claims that are consistent with this disclosure are contemplated and may be claimed in this or another application. In short, combinations are not limited to those specifically enumerated in the appended claims.

Where appropriate, it is also contemplated that claims drafted in one format or statutory type (e.g., apparatus) are intended to support corresponding claims of another format or statutory type (e.g., method).

Because this disclosure is a legal document, various terms and phrases may be subject to administrative and judicial interpretation. Public notice is hereby given that the following paragraphs, as well as definitions provided throughout the disclosure, are to be used in determining how to interpret claims that are drafted based on this disclosure.

References to a singular form of an item (i.e., a noun or noun phrase preceded by “a,” “an,” or “the”) are, unless context clearly dictates otherwise, intended to mean “one or more.” Reference to “an item” in a claim thus does not, without accompanying context, preclude additional instances of the item. A “plurality” of items refers to a set of two or more of the items.

The word “may” is used herein in a permissive sense (i.e., having the potential to, being able to) and not in a mandatory sense (i.e., must).

The terms “comprising” and “including,” and forms thereof, are open-ended and mean “including, but not limited to.”

When the term “or” is used in this disclosure with respect to a list of options, it will generally be understood to be used in the inclusive sense unless the context provides otherwise. Thus, a recitation of “x or y” is equivalent to “x or y, or both,” and thus covers 1) x but not y, 2) y but not x, and 3) both x and y. On the other hand, a phrase such as “either x or y, but not both” makes clear that “or” is being used in the exclusive sense.

A recitation of “w, x, y, or z, or any combination thereof” or “at least one of . . . W, x, y, and z” is intended to cover all possibilities involving a single element up to the total number of elements in the set. For example, given the set [w, x, y, z], these phrasings cover any single element of the set (e.g., w but not x, y, or z), any two elements (e.g., w and x, but not y or z), any three elements (e.g., w, x, and y, but not z), and all four elements. The phrase “at least one of . . . w, x, y, and z” thus refers to at least one element of the set [w, x, y, z], thereby covering all possible combinations in this list of elements. This phrase is not to be interpreted to require that there is at least one instance of w, at least one instance of x, at least one instance of y, and at least one instance of z.

Various “labels” may precede nouns or noun phrases in this disclosure. Unless context provides otherwise, different labels used for a feature (e.g., “first circuit,” “second circuit,” “particular circuit,” “given circuit,” etc.) refer to different instances of the feature. Additionally, the labels “first,” “second,” and “third” when applied to a feature do not imply any type of ordering (e.g., spatial, temporal, logical, etc.), unless stated otherwise.

The phrase “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

The phrases “in response to” and “responsive to” describe one or more factors that trigger an effect. This phrase does not foreclose the possibility that additional factors may affect or otherwise trigger the effect, either jointly with the specified factors or independent from the specified factors. That is, an effect may be solely in response to those factors, or may be in response to the specified factors as well as other, unspecified factors. Consider the phrase “perform A in response to B.” This phrase specifies that B is a factor that triggers the performance of A, or that triggers a particular result for A. This phrase does not foreclose that performing A may also be in response to some other factor, such as C. This phrase also does not foreclose that performing A may be jointly in response to B and C. This phrase is also intended to cover an embodiment in which A is performed solely in response to B. As used herein, the phrase “responsive to” is synonymous with the phrase “responsive at least in part to.” Similarly, the phrase “in response to” is synonymous with the phrase “at least in part in response to.”

Within this disclosure, different entities (which may variously be referred to as “units,” “circuits,” other components, etc.) may be described or claimed as “configured” to perform one or more tasks or operations. This formulation is used herein to refer to structure (i.e., something physical). More specifically, this formulation is used to indicate that this structure is arranged to perform the one or more tasks during operation. A structure can be said to be “configured to” perform some tasks even if the structure is not currently being operated. Thus, an entity described or recited as being “configured to” perform some tasks refers to something physical, such as a device, circuit, a system having a processor unit and a memory storing program instructions executable to implement the task, etc. This phrase is not used herein to refer to something intangible.

In some cases, various units/circuits/components may be described herein as performing a set of tasks or operations. It is understood that those entities are “configured to” perform those tasks/operations, even if not specifically noted.

The term “configured to” is not intended to mean “configurable to.” An unprogrammed FPGA, for example, would not be considered to be “configured to” perform a particular function. This unprogrammed FPGA may be “configurable to” perform that function, however. After appropriate programming, the FPGA may then be said to be “configured to” perform the particular function.

Various units, circuits, or other components may be described as “configured to” perform a task or tasks. In such contexts, “configured to” is a broad recitation of structure generally meaning “having circuitry that” performs the task or tasks during operation. As such, the unit/circuit/component can be configured to perform the task even when the unit/circuit/component is not currently on. In general, the circuitry that forms the structure corresponding to “configured to” may include hardware circuits. Similarly, various units/circuits/components may be described as performing a task or tasks, for convenience in the description. Such descriptions should be interpreted as including the phrase “configured to.” Reciting a unit/circuit/component that is configured to perform one or more tasks is expressly intended not to invoke 35 U.S.C. § 112, paragraph (f) interpretation for that unit/circuit/component. More generally, the recitation of any element is expressly intended not to invoke 35 U.S.C. § 112, paragraph (f) interpretation for that element unless the language “means for” or “step for” is specifically recited. Should Applicant wish to invoke Section 112(f) during prosecution of a United States patent application based on this disclosure, it will recite claim elements using the “means for” performing a function construct.

Different “circuits” may be described in this disclosure. These circuits or “circuitry” constitute hardware that includes various types of circuit elements, such as combinatorial logic, clocked storage devices (e.g., flip-flops, registers, latches, etc.), finite state machines, memory (e.g., random-access memory, embedded dynamic random-access memory), programmable logic arrays, and so on. Circuitry may be custom designed, or taken from standard libraries. In various implementations, circuitry can, as appropriate, include digital components, analog components, or a combination of both. Certain types of circuits may be commonly referred to as “units” (e.g., a decode unit, an arithmetic logic unit (ALU), functional unit, memory management unit (MMU), etc.). Such units also refer to circuits or circuitry.

The disclosed circuits/units/components and other elements illustrated in the drawings and described herein thus include hardware elements such as those described in the preceding paragraph. In many instances, the internal arrangement of hardware elements within a particular circuit may be specified by describing the function of that circuit. For example, a particular “decode unit” may be described as performing the function of “processing an opcode of an instruction and routing that instruction to one or more of a plurality of functional units,” which means that the decode unit is “configured to” perform this function. This specification of function is sufficient, to those skilled in the computer arts, to connote a set of possible structures for the circuit.

In various embodiments, as discussed in the preceding paragraph, circuits, units, and other elements may be defined by the functions or operations that they are configured to implement. The arrangement and such circuits/units/components with respect to each other and the manner in which they interact form a microarchitectural definition of the hardware that is ultimately manufactured in an integrated circuit or programmed into an FPGA to form a physical implementation of the microarchitectural definition. Thus, the microarchitectural definition is recognized by those of skill in the art as structure from which many physical implementations may be derived, all of which fall into the broader structure described by the microarchitectural definition. That is, a skilled artisan presented with the microarchitectural definition supplied in accordance with this disclosure may, without undue experimentation and with the application of ordinary skill, implement the structure by coding the description of the circuits/units/components in a hardware description language (HDL) such as Verilog or VHDL. The HDL description is often expressed in a fashion that may appear to be functional. But to those of skill in the art in this field, this HDL description is the manner that is used to transform the structure of a circuit, unit, or component to the next level of implementational detail. Such an HDL description may take the form of behavioral code (which is typically not synthesizable), register transfer language (RTL) code (which, in contrast to behavioral code, is typically synthesizable), or structural code (e.g., a netlist specifying logic gates and their connectivity). The HDL description may subsequently be synthesized against a library of cells designed for a given integrated circuit fabrication technology, and may be modified for timing, power, and other reasons to result in a final design database that is transmitted to a foundry to generate masks and ultimately produce the integrated circuit. Some hardware circuits or portions thereof may also be custom-designed in a schematic editor and captured into the integrated circuit design along with synthesized circuitry. The integrated circuits may include transistors and other circuit elements (e.g. passive elements such as capacitors, resistors, inductors, etc.) and interconnect between the transistors and circuit elements. Some embodiments may implement multiple integrated circuits coupled together to implement the hardware circuits, and/or discrete elements may be used in some embodiments. Alternatively, the HDL design may be synthesized to a programmable logic array such as a field programmable gate array (FPGA) and may be implemented in the FPGA. This decoupling between the design of a group of circuits and the subsequent low-level implementation of these circuits commonly results in the scenario in which the circuit or logic designer never specifies a particular set of structures for the low-level implementation beyond a description of what the circuit is configured to do, as this process is performed at a different stage of the circuit implementation process.

The fact that many different low-level combinations of circuit elements may be used to implement the same specification of a circuit results in a large number of equivalent structures for that circuit. As noted, these low-level circuit implementations may vary according to changes in the fabrication technology, the foundry selected to manufacture the integrated circuit, the library of cells provided for a particular project, etc. In many cases, the choices made by different design tools or methodologies to produce these different implementations may be arbitrary.

Moreover, it is common for a single implementation of a particular functional specification of a circuit to include, for a given embodiment, a large number of devices (e.g., millions of transistors). Accordingly, the sheer volume of this information makes it impractical to provide a full recitation of the low-level structure used to implement a single embodiment, let alone the vast array of equivalent possible implementations. For this reason, the present disclosure describes structure of circuits using the functional shorthand commonly employed in the industry.

Numerous variations and modifications will become apparent to those skilled in the art once the above disclosure is fully appreciated. It is intended that the following claims be interpreted to embrace all such variations and modifications.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

What is claimed is:

1. A clock compensation circuit comprising:
a phase detector circuit comprising a first input operative to receive a first clock signal from a first integrated circuit, a second input operative to receive a second clock signal for a circuit of a second integrated circuit, and configured to output a first control signal indicating whether the first clock signal and the second clock signal are synchronized, and a second control signal indicating whether a phase of the second clock signal is different than the first clock signal;
a control circuit, operatively responsive to at least one of the first and second control signals, and configured to generate one or more delay control signals; and
a delay circuit, operatively responsive to the one or more delay control signals, and configured to apply a delay to the second clock signal based on the one or more delay control signals.

2. The clock compensation circuit of claim 1, wherein after applying the delay to the second clock signal, the phase detector circuit is further configured to: output another first control signal indicating whether the first clock signal and the delayed second clock signal are synchronized, and another second control signal indicating whether a phase of the delayed second clock signal is different than the first clock signal.

3. The clock compensation circuit of claim 1, wherein the phase detector circuit comprises an exclusive OR (XOR) circuit configured to determine that the second clock signal is not synchronized with the first clock signal.

4. The clock compensation circuit of claim 3 wherein the delay circuit comprises a programmable delay line that is controlled based on the one or more delay control signals.

5. The clock compensation circuit of claim 3 wherein the phase detector circuit comprises a buffer, a first latch responsive to the first clock signal, and a second latch responsive to the first clock signal, the buffer coupled to receive the second clock signal and output an adjusted clock signal to the first latch, the first latch operably coupled to provide a first output to a first input of the XOR circuit, the second latch configured to receive the second clock signal and provide a second output to a second input of the XOR circuit and the XOR circuit is configured to output the first control signal.

6. The clock compensation circuit of claim 5, wherein the second latch is configured to output the second output as the second control signal.

7. An apparatus comprising:
a first die operatively coupled to a first voltage domain;
a second die electrically coupled to the first die through an interposer, and operatively coupled to a second voltage domain having a different voltage level than the first voltage domain; and
the first die comprising a clock generator circuit configured to generate a first clock signal and comprising a first circuit operatively responsive to the first clock signal; and
wherein the second die comprises a second circuit that is operatively coupled to the first circuit, the second die configured to receive the first clock signal from the first die and provide a second clock signal to the second circuit based on the first clock signal, and wherein the second die comprises clock compensation circuitry configured to:
compare the first clock signal and the second clock signal; and
cause a delay to be applied to the second clock signal, based on comparing the first clock signal and the second clock signal.

8. The apparatus of claim 7, wherein the clock compensation circuitry comprises:
a phase detector circuit configured to generate one or more control signals based on the comparison of the first clock signal and the second clock signal, indicating that the second clock signal is not synchronized with the first clock signal;
a control circuit, operatively responsive to the one or more control signals from the phase detector circuit, and configured to generate one or more delay control signals; and
a delay circuit, operatively responsive to the one or more delay control signals, and configured to apply the delay to the second clock signal based on the one or more delay control signals.

9. The apparatus of claim 8, wherein the clock compensation circuitry after applying the delay to the second clock signal, the phase detector circuit is further configured to: output another first control signal indicating whether the first clock signal and the delayed second clock signal are synchronized, and another second control signal indicating whether a phase of the delayed second clock signal is different than the first clock signal.

10. The apparatus of claim 8 wherein the phase detector circuit is configured to generate the one or more control signals to indicate a timing of the second clock signal is different than the first clock signal.

11. The apparatus of claim 8 wherein the first die and the second die are fabricated from different silicon material and the first and second circuits communicate data through the interposer based on a synchronized first clock signal and second clock signal.

12. The apparatus of claim 8 wherein the phase detector circuit comprises an exclusive OR (XOR) circuit configured to determine that the second clock signal is not synchronized with the first clock signal.

13. The apparatus of claim 12 wherein the phase detector circuit comprises a buffer, a first latch responsive to the first clock signal, and a second latch responsive to the first clock signal, the buffer coupled to receive the second clock signal and output an adjusted clock signal to the first latch, the first latch operably coupled to provide a first output to a first input of the XOR circuit, the second latch configured to receive the second clock signal and provide a second output to a second input of the XOR circuit and the XOR circuit is configured to output the first control signal.

14. A method comprising:
generating by a first integrated circuit, a first clock signal for a first circuit of the first integrated circuit;
providing, by the first integrated circuit, the first clock signal to a second integrated circuit that comprises a second circuit that is operatively coupled to the first circuit;
generating, by the second integrated circuit, a second clock signal for the second circuit based on the first clock signal;
comparing, by the second integrated circuit, the first clock signal and the second clock signal; and
in response to the comparison, adjusting by the second integrated circuit, a delay of the second clock signal that causes synchronization of the first clock signal and the second clock signal.

15. The method of claim 14 comprising:
producing, by the second integrated circuit, one or more control signals indicating that the second clock signal is not synchronized with the first clock signal; and
generating, by the second integrated circuit, one or more delay control signals that cause the delay to be applied to the second clock signal.

16. The method of claim 14 comprising:
after adjusting the delay of the second clock signal, producing a first control signal indicating whether the first clock signal and a delayed second clock signal are synchronized, and producing another second control signal indicating whether a phase of the delay second clock signal is different than the first clock signal.

17. The method of claim 15 comprising producing the one or more control signals to indicate that a timing of the second clock signal is different than the first clock signal.

18. The method of claim 15, comprising producing the delay by programming a programmable delay line that is controlled based on the one or more delay control signals.

19. The method of claim 15 comprising continuing to adjust the delay of the second clock signal until a timing of the first clock signal and the second clock signal are locked.

20. The method of claim 14 comprising performing operations between the first circuit and the second circuit based on a synchronized first clock signal and second clock signal.
